(19) United States
(12) Patent Application Publication
(10) Pub. No.: US 2025/0151251 A1
(43) Pub. Date: May 8, 2025

(54) PORTABLE BAKING ASSEMBLY TO CURE THERMAL INTERFACE MATERIAL FOR PROCESSING UNITS

(71) Applicant: ZT GROUP INT'L, INC. DBA ZT SYSTEMS, SECAUCUS, NJ (US)

(72) Inventors: Sruti Chigullapalli, Seattle, WA (US); Paul Anderson, Leander, TX (US); SunilKumar Pinnu, Jersey City, NJ (US)

(21) Appl. No.: 18/501,952

(22) Filed: Nov. 3, 2023

(51) Int. Cl. H05K 13/04; H05K 3/30

(52) U.S. Cl. CPC H05K 13/0447; H05K 3/303; H05K 2203/081; H05K 2203/11

(57) ABSTRACT

A portable baking assembly includes a portable housing, a receiving base, and an air flow assembly. The receiving base is disposed in the portable housing. The receiving base is operable to receive a processing unit assembly including a processing unit, a thermal solution, and a thermal interface material operable to couple the processing unit and the thermal solution. The air flow assembly is received in the portable housing and in fluid communication with the receiving base. The air flow assembly includes an inlet conduit that is operable to receive heated air and direct the heated air towards the receiving base to heat the processing unit assembly and cure the thermal interface material.

### FIELD

The present disclosure relates generally to a portable baking assembly operable to cure thermal interface material to couple a processing unit with a thermal solution.

### BACKGROUND

Processing units such as graphics processing units (GPUs) bond with thermal solutions (e.g., heatsinks and/or cold plates) using a phase change thermal interface material. The smallest of voids in the thermal interface material can make a GPU throttle thermally which can result in a huge performance loss, for example at a cluster level artificial intelligence or machine learning workload. The slowest processing unit can slow down the entire cluster.

### BRIEF DESCRIPTION OF THE DRAWINGS

Implementations of the present technology will now be described, by way of example only, with reference to the attached figures, wherein:

FIG. 1A illustrates a portable system with a processing unit assembly;

FIG. 1B illustrates the portable system with the processing unit assembly separated from the portable system;

FIG. 1C illustrates an exploded view of the portable system with the processing unit assembly;

FIG. 2 illustrates a front view of the portable system;

FIG. 3A illustrates a rear view of the portable system;

FIG. 3B illustrates an exploded view of the processing unit assembly and an air flow assembly of the portable system;

FIG. 3C illustrates a diagram of the air flow assembly directing air through the portable system to heat the processing unit assembly;

FIG. 3D illustrates a cross-sectional diagram of FIG. 3C; and

FIG. 4 illustrates a diagram of a controller.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented. The term “coupled” is defined as connected, whether directly or indirectly through intervening components, and is not necessarily limited to physical connections. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “about” means reasonably close to the particular value. For example, about does not require the exact measurement specified and can be reasonably close. As used herein, the word “about” can include the exact number. The term “near” as used herein is within a short distance from the particular mentioned object. The term “near” can include abutting as well as relatively small distance beyond abutting. The terms “comprising,” “including” and “having” are used interchangeably in this disclosure. The terms “comprising,” “including” and “having” mean to include, but not necessarily be limited to the things so described.

Processing units (e.g., GPUs) are bare-die and need a thermal interface material to bond with the thermal solution (heatsinks for air-cooled and cold plate for liquid-cooled) inside the corresponding computing system (e.g., personal computers, artificial intelligence or machine learning servers, etc.). The thermal interface material can include a phase change material and needs an activation temperature of greater than 50 degrees Celsius to phase change, flow, and fill all of the voids, thereby creating a perfect attachment between the die and the thermal solution, with lowest thermal resistance. This process can be particularly difficult to do with cold plates which can be filled with cold fluid at less than 40 degrees Celsius in liquid cooled computing systems. This process becomes increasingly difficult if bonding of the processing unit with the thermal solution needs to be performed in the field.

Additionally, conventional systems can have large variations in thermal performance which do not show up at the time of replacement but manifest at a later time after deployment in the computing systems. Since one processing unit is all it takes to tank the performance of an entire processing unit cluster, it is critical to have a quick but robust and repeatable system for thermal interface material phase change and curing processes for processing units in the field to ensure high availability of processing units and minimal downtime.

The portable baking assembly disclosed herein can be used in combination with a standard heat gun to create a quick and easy way to cure the thermal interface material between the thermal solution and the processing unit in the field. The portable baking assembly removes operator error and provides consistent bake time and full coverage of the thermal interface material.

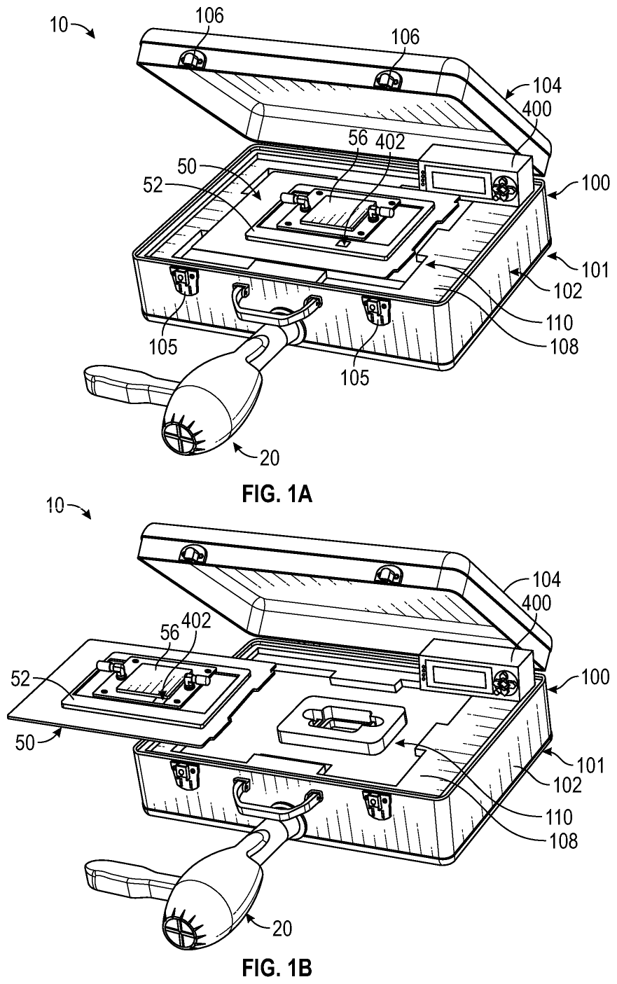

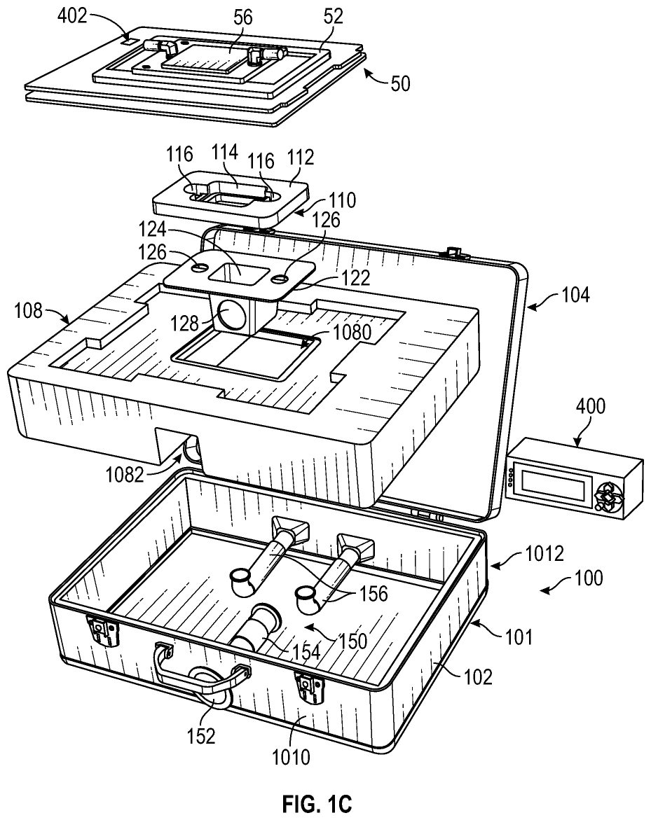

The disclosure now turns to FIGS. 1A, 1B, and 1C, which illustrate an example of a portable baking assembly 10. The portable baking assembly 10 can be operable to change out a processing unit assembly 50 in the field with no access to manufacturing jigs or tools. The portable baking assembly 10 can include a portable housing 101 and a heating device 20 operable to deliver heated air.

The heating device 20 can include, for example, a heat gun. In some examples, the heating device 20 can include an adjustable temperature heat gun so that the temperature can be controlled to efficiently and effectively bake and cure the thermal interface material. In some examples, the heating device 20 can be removably coupled with the portable housing 101. In some examples, the heating device 20 can be integrated with the portable housing 101. In some examples, the heating device 20 can be included in the portable housing 101.

The portable housing 101 can include an easy carry case. The portable housing 101 can include a base 102 and a lid 104. The lid 104 can be operable to cover the base 102. In at least one example, the lid 104 can be hingedly coupled with the base 102. In some examples, the lid 104 can be detachably coupled with the base 102. In some examples, the portable housing 101 encompasses the components of the portable baking assembly 10. In some examples, the user only needs to carry around the portable housing 101 and the heating device 20, which limits the number and size of components for being able to replace and/or cure thermal interface material in a processing unit assembly 50. Accordingly, the portable baking assembly 10 can be utilized in the field.

The portable housing 101 can include a front side 1010 which is proximate the user and a rear side 1012 which is pointed away from the user. The rear side 1012 can be opposite the user in relation to the portable housing 101.

The portable housing 101 can also include a locking mechanism 105, 106 to prevent the lid 104 from undesirably opening and separating from the base 102. For example, as illustrated in FIGS. 1A, 1B, and 1C, the locking mechanism 105, 106 can include one or more latches 105 included on the base 102 and one or more corresponding keepers 106 included on the lid 104. The latches 105 are operable to couple with the keepers 106 to prevent the lid 104 from opening until the locking mechanism 105, 106 is unlocked. Accordingly, the portable baking assembly 10 can be securely stored and transported in the field.

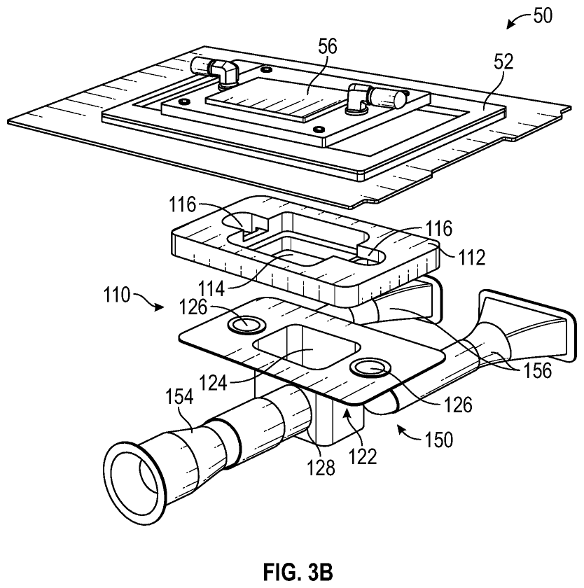

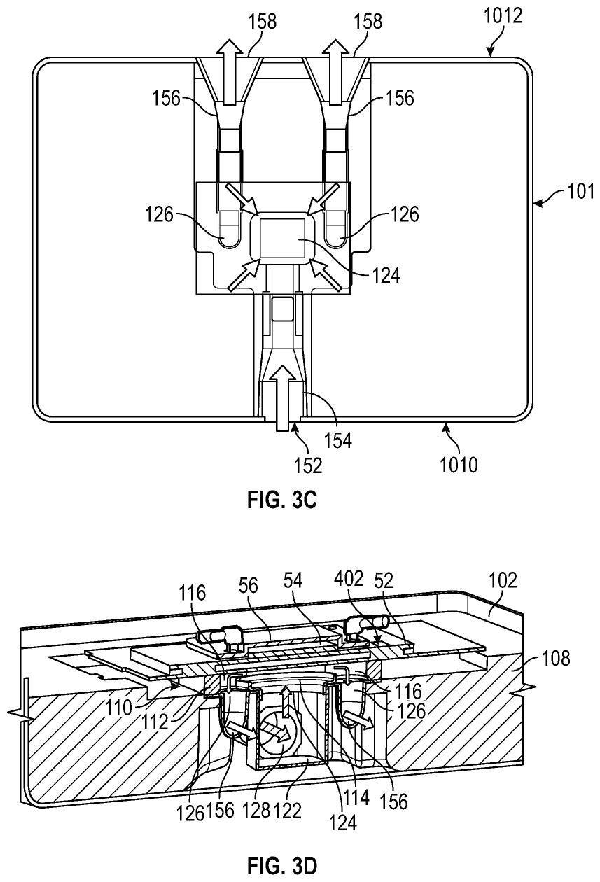

The processing unit assembly 50 can include a processing unit 52, a thermal solution 56, and a thermal interface material 54 (shown in FIG. 3D). The thermal solution 56 can include, for example, a cold plate and/or a heatsink. The thermal solution 56 can be operable to manage the temperature of the processing unit 52 to prevent overheating and damage to the processing unit 52. In some examples, the thermal solution 56 can control the temperature of the processing unit 52 via fluids (e.g., water and/or coolant) and/or air flow. In some examples, the thermal solution 56 can include one or more fluid ports operable to provide inlet and outlet flow of the fluid into the thermal solution 56 to manage the temperature of the processing unit 52.

The thermal interface material 54 can be operable to couple the processing unit 52 and the thermal solution 56. The thermal interface material 54 can be positioned between the processing unit 52 and the thermal solution 56. The thermal interface material 54 can be sandwiched between the processing unit 52 and the thermal solution 56. The thermal interface material 54 bonds the processing unit 52 with the thermal solution 56. The thermal interface material 54 can include a phase change material. The thermal interface material 54 can be activated at a temperature greater than 50 degrees Celsius to change phase, flow, and fill all the voids between the processing unit 52 and the thermal solution 56 to successfully create an attachment between the processing unit 52 and the thermal solution 56, with the lowest thermal resistance. In particular, filling the voids and providing low thermal resistance between the processing unit 52 and the thermal solution 56 can be difficult to do with cold plates that are filled with cold fluid at less than 40 degrees Celsius. Moreover, the ambient temperature in the field can create a difficult environment to bake the thermal interface material 54. The portable baking system 10 as disclosed herein can prevent curing issues such as voids, overflow, and/or insufficient baking which can create a lot of quality issues not only at time zero but also down the road after the processing unit assembly 50 is deployed in the computing systems. In some examples where the processing unit assembly 50 is utilized in data centers, one processing unit throttling due to thermal issues can tank the performance of the entire processing cluster.

The portable baking assembly 10 includes a receiving base 110 disposed in the portable housing 101. The receiving base 110 can be operable to receive the processing unit assembly 50. In some examples, the receiving base 110 can also be operable to direct the heated air from the heating device 20 towards the processing unit assembly 50 and in such a way that the processing unit assembly 50 is heated evenly and efficiently so that the thermal interface material 54 cures and distributes evenly with minimal voids or without voids. In some examples, the receiving base 110 can also be operable to direct the heated air towards an exhaust to flow out of the portable housing 101.

The portable baking assembly 10 also includes an air flow assembly 150 received in the portable housing 101 and in fluid communication with the receiving base 110. The air flow assembly 150 can include an inlet conduit 154. The inlet conduit 154 can be operable to receive heated air (e.g., from the heating device 20) and direct the heated air towards the receiving base 110 to heat the processing unit assembly 50 and cure the thermal interface material 54. In at least one example, the air flow assembly 150 can include an exhaust 156 in fluid communication with the receiving base 110. The receiving base 110 can be operable to direct the heated air towards the exhaust 156 to flow out of the portable housing 101. Accordingly, the temperature being applied to the processing unit assembly 50 can be controlled and is not too high.

With the air flow assembly 150 and the receiving base 110, the heated air from the heating device 20 can be directed towards the processing unit assembly 20 to effectively and efficiently cure the thermal interface material 54 in the field.

In at least one example, as illustrated in FIGS. 1A-1C, the portable baking assembly 10 can include an insulative layer 108 received in the portable housing 101. The insulative layer 108 can be operable to receive the inlet conduit 154 and the receiving base 110. For example, the insulative layer 108 can form a receiving aperture 1080 that is operable to receive the receiving base 110 and also an inlet aperture 1082 operable to receive the inlet conduit 154. The insulative layer 108 can include a high-density foam. In at least one example, the insulative layer 108 can be anti-static and non-conductive. Accordingly, the heated air from the heating device 20 can be focused on the processing unit assembly 50. Also, the insulative layer 108 can prevent the portable housing 101 to reach a temperature which the user cannot hold onto the portable housing 101, and/or which the portable housing 101 may damage the environment.

In at least one example, a thermocouple 402 can be operable to measure the temperature of the thermal interface material 54. In some examples, the thermocouple 402 can measure the temperature of the processing unit assembly 50 which can provide data on the curing of the thermal interface material 54. In at least one example, the thermocouple 402 can be disposed on the processing unit assembly 50. In some examples, the thermocouple 402 can be disposed in the portable housing 101 and directed to measure the temperature of the processing unit assembly 50 (e.g., the thermal interface material 54). In at least one example, the thermocouple 402 can be disposed on the receiving base 110.

In at least one example, a controller 400 can be communicably coupled with the thermocouple 402. The controller 400 can be operable to receive the measured temperature of the thermal interface material 402. In at least one example, the controller 400 can indicate to a user the temperature of the processing unit assembly 50 (e.g., the thermal interface material 54). In at least one example, the controller 400 can be operable to determine when the thermal interface material 54 is cured based on the temperature and time that the processing unit assembly 50 is exposed to the heated air from the heating device 20. In at least one example, the controller 400 can be operable to indicate to a user that the thermal interface material 54 is cured. In at least one example, the controller 400 can include a timer.

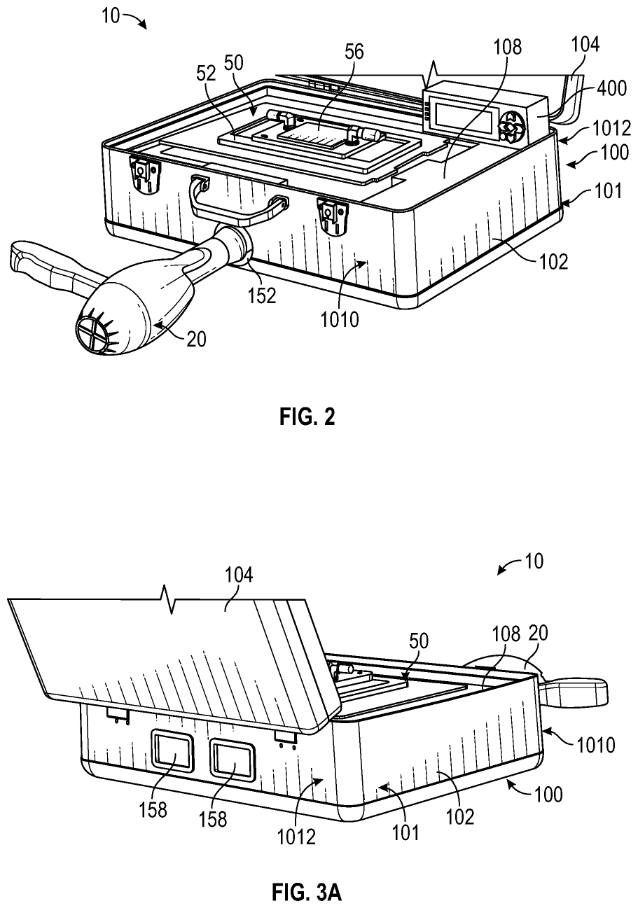

FIG. 2 illustrates that the heating device 20 can be operable to provide the heated air through the front side 1010 of the portable housing 101. For example, as illustrated in FIG. 2, the front side 1010 of the portable housing 101 can form an inlet 152 through which the heating device 20 can direct heated air into the inlet conduit 154. The inlet conduit 154 can be in fluid communication with the inlet 152. In at least one example, the inlet 152 can be configured to receive at least a portion of the heating device 20 (e.g., the nozzle). In at least one example, the inlet 152 can be operable to couple with the heating device 20 such that the user does not have to continually hold onto the heating device 20. The heating device 20 being in communication with the inlet 152 in the front side 1010 of the portable housing 101 allows the user to easily control the heating device 20.

FIG. 3A illustrates that the portable baking assembly 10 can form one or more outlets 158 in the rear side 1012 of the portable housing 101 opposite the inlet 152 formed in the front side 1010. The outlets 158 can be in fluid communication with the exhaust(s) 156. The heated air, after flowing across the processing unit assembly 50 in the receiving base 110, is directed out of the portable housing 101 through the exhausts 156 opposite the inlet 152 and out the outlets 158 in the rear side 1012. Accordingly, the hot air is safely ejected away from the user.

FIGS. 3B, 3C, and 3D illustrate the receiving base 110 and the air flow assembly 150 directs the heated air from the heating device 20 to the processing unit assembly 50 and out the exhaust 156.

In at least one example, as illustrated in FIG. 3B, the receiving base 110 can include a flow adapter 112. The flow adapter 112 can be operable to direct the heated air to flow across the processing unit assembly 50 to uniformly heat the processing unit assembly 50 and cure the thermal interface material 54 such that the thermal interface material 54 distributes evenly with minimal voids or without voids. The flow adapter 112 can form an inlet aperture 114 and one or more exhaust apertures 116. The one or more exhaust apertures 116 can be formed about the inlet aperture 114 such that the inlet aperture 114 is substantially in the middle of the exhaust apertures 116. While FIG. 3B illustrates the flow adapter 112 with two exhaust apertures 116 on opposing sides of the inlet aperture 114, in other examples, one, three, or more exhaust apertures 116 can be included. Similarly, more than one inlet aperture 114 can be included.

The inlet aperture 114 can be in fluid communication with the inlet 152 and/or the inlet conduit 154 to direct the heat to the processing unit assembly 50. The exhaust aperture 116 can be operable to be in fluid communication with the exhaust 156 and/or the outlet 158 such that the heated air flows from the inlet 152 through the inlet aperture 114 to the processing unit assembly 50 and then from the processing unit assembly 50 through the exhaust aperture 116 to the exhaust 156 and out of the portable housing 101. The inlet aperture 114 and the exhaust apertures 116 can be in fluid communication with one another such that the heated air can flow in via the inlet aperture 114 to heat the processing unit assembly 50 and then flow out to the exhaust(s) 156 via the exhaust apertures 116.

The inlet aperture 114 can be positioned such that the inlet aperture is in line with the thermal interface material 54. Accordingly, with the receiving base 110, the heated air is concentrated on the thermal interface material 54 to efficiently and effectively distribute and cure the thermal interface material 54 in the processing unit assembly 50.

In at least one example, a conditioning nozzle 122 can be included in the portable baking assembly 10. The conditioning nozzle 122 can be operable to be fluidly coupled with the inlet conduit 154 and the exhaust(s) 156. The conditioning nozzle 122 can also be in fluid communication with the flow adapter 112. Accordingly, the conditioning nozzle 122 can be operable to direct the heated air from the inlet conduit 154 towards the inlet aperture 114 of the flow adapter 112 and direct the air from the exhaust aperture(s) 116 of the flow adapter 112 to the exhaust(s) 156. The conditioning nozzle 122 can include an inlet receiver 128 operable to receive and/or fluidly couple with the inlet conduit 154. In some examples, the inlet receiver 128 can be directly coupled with the inlet 152. The inlet receiver 128 can be in fluid communication with an inlet opening 124 which is in fluid communication with the inlet aperture 114 of the flow adapter 112. For example, the flow adapter 112 can be positioned on top of the conditioning nozzle 122 such that the inlet aperture 114 and the inlet opening 124 are aligned. One or more exhaust ports 126 can be in fluid communication with the exhaust aperture(s) 116 of the flow adapter 112. The exhaust ports 126 can be operable to receive and/or be fluidly coupled with the exhaust(s) 156. Accordingly, the air can flow from the processing unit assembly 50 to the exhaust apertures 116 of the flow adapter 112, to the exhaust ports 126, into the exhausts 156, and out the outlet 158 to exit the portable housing 101. The conditioning nozzle 122 can provide directed air flow in and out of the portable housing 101, and the conditioning nozzle 122 can direct the air flow to and from the processing unit assembly 50.

With the receiving base 110 and the conditioning nozzle 122, the air flow is optimized for uniform heating of the processing unit assembly 50 from underneath. Accordingly, the thermal interface material 54 can be efficiently and effectively distributed and cured in the processing unit assembly 50 in the field by the portable baking assembly 10.

The portable baking assembly 10 provides a quick and easy way to cure the thermal interface material 54 between the thermal solution 56 and the processing unit 52 in the field. The portable baking assembly 10 removes operator error from the equation and provides consistent bake time and full coverage of the thermal interface material 54.

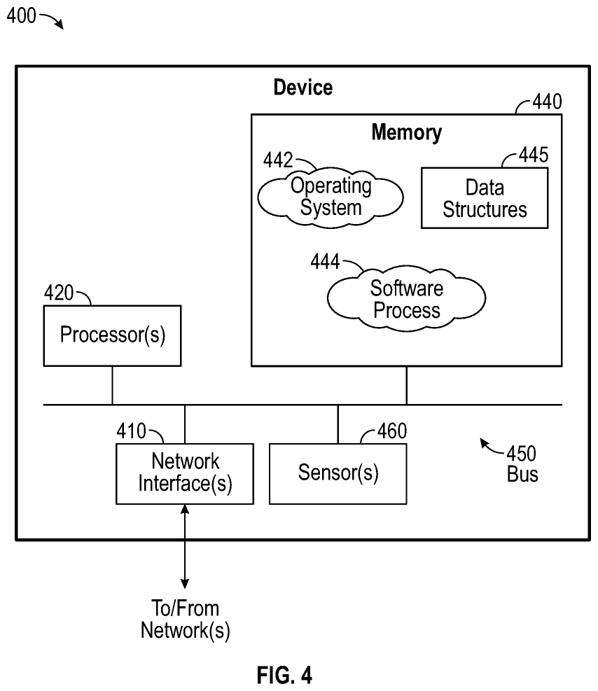

FIG. 4 is a block diagram of an exemplary controller 400. Controller 400 is configured to perform processing of data and communicate with the sensors 402, for example as illustrated in FIGS. 1A and 1B. In operation, controller 400 communicates with one or more of the above-discussed components and may also be configured to communication with remote devices/systems.

As shown, controller 400 includes hardware and software components such as network interfaces 410, at least one processor 420, sensors 460 and a memory 440 interconnected by a system bus 450. Network interface(s) 410 can include mechanical, electrical, and signaling circuitry for communicating data over communication links, which may include wired or wireless communication links. Network interfaces 410 are configured to transmit and/or receive data using a variety of different communication protocols, as will be understood by those skilled in the art.

Processor 420 represents a digital signal processor (e.g., a microprocessor, a microcontroller, or a fixed-logic processor, etc.) configured to execute instructions or logic to perform tasks in the portable baking assembly 10. Processor 420 may include a general purpose processor, special-purpose processor (where software instructions are incorporated into the processor), a state machine, application specific integrated circuit (ASIC), a programmable gate array (PGA) including a field PGA, an individual component, a distributed group of processors, and the like. Processor 420 typically operates in conjunction with shared or dedicated hardware, including but not limited to, hardware capable of executing software and hardware. For example, processor 420 may include elements or logic adapted to execute software programs and manipulate data structures 445, which may reside in memory 440.

Sensors 460, which may include sensors 402 as disclosed herein, typically operate in conjunction with processor 420 to perform measurements, and can include special-purpose processors, detectors, transmitters, receivers, and the like. In this fashion, sensors 460 may include hardware/software for generating, transmitting, receiving, detection, logging, and/or sampling temperatures, air flow, and/or other parameters.

Memory 440 comprises a plurality of storage locations that are addressable by processor 420 for storing software programs and data structures 445 associated with the embodiments described herein. An operating system 442, portions of which may be typically resident in memory 440 and executed by processor 420, functionally organizes the device by, inter alia, invoking operations in support of software processes and/or services 444 executing on controller 400. These software processes and/or services 444 may perform processing of data and communication with controller 400, as described herein. Note that while process/service 444 is shown in centralized memory 440, some examples provide for these processes/services to be operated in a distributed computing network.

It will be apparent to those skilled in the art that other processor and memory types, including various computer-readable media, may be used to store and execute program instructions pertaining to the thermal interface material baking and curing techniques described herein. Also, while the description illustrates various processes, it is expressly contemplated that various processes may be embodied as modules having portions of the process/service 444 encoded thereon. In this fashion, the program modules may be encoded in one or more tangible computer readable storage media for execution, such as with fixed logic or programmable logic (e.g., software/computer instructions executed by a processor, and any processor may be a programmable processor, programmable digital logic such as field programmable gate arrays or an ASIC that comprises fixed digital logic. In general, any process logic may be embodied in processor 420 or computer readable medium encoded with instructions for execution by processor 420 that, when executed by the processor, are operable to cause the processor to perform the functions described herein.

Additionally, the controller 400 can apply machine learning, such as a neural network or sequential logistic regression and the like, to determine relationships between the temperature measurements received by the sensors 402. For example, a deep neural network may be trained in advance to capture the complex relationship between the temperature measurements and the curing and distribution of the thermal interface material 54. This neural net can then be deployed in the adjustment of heated air flow to better cure the thermal interface material 54.

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure to the full extent indicated by the broad general meaning of the terms used in the attached claims. It will therefore be appreciated that the embodiments described above may be modified within the scope of the appended claims.

What is claimed is:

1. A portable baking assembly comprising:
a portable housing;
a receiving base disposed in the portable housing, the receiving base operable to receive a processing unit assembly including a processing unit, a thermal solution, and a thermal interface material operable to couple the processing unit and the thermal solution; and
an air flow assembly received in the portable housing and in fluid communication with the receiving base, the air flow assembly including an inlet conduit, wherein the inlet conduit is operable to receive heated air and direct the heated air towards the receiving base to heat the processing unit assembly and cure the thermal interface material.

2. The portable baking assembly of claim 1, wherein the air flow assembly includes an exhaust in fluid communication with the receiving base.

3. The portable baking assembly of claim 2, wherein the receiving base directs the heated air towards the exhaust to flow out of the portable housing.

4. The portable baking assembly of claim 3, wherein the exhaust directs the heated air out of the portable housing opposite the inlet.

5. The portable baking assembly of claim 1, wherein the receiving base includes a flow adapter, the flow adapter operable to direct the heated air to flow across the processing unit assembly to uniformly heat the processing unit assembly and cure the thermal interface material.

6. The portable baking assembly of claim 4, wherein the flow adapter forms an inlet aperture and an exhaust aperture, wherein the inlet aperture is in fluid communication with the inlet to direct the heat to the processing unit assembly, wherein the exhaust aperture is operable to be in fluid communication with an exhaust such that the heated air flows from the inlet through the inlet aperture to the processing unit assembly and from the processing unit assembly through the exhaust aperture to the exhaust and out of the portable housing.

7. The portable baking assembly of claim 1, further comprising an insulative layer received in the portable housing, wherein the insulative layer is operable to receive the inlet conduit and the receiving base.

8. The portable baking assembly of claim 7, wherein the insulative layer includes a high-density foam.

9. The portable baking assembly of claim 7, wherein the insulative layer is anti-static and non-conductive.

10. The portable baking assembly of claim 1, further comprising a thermocouple operable to measure the temperature of the thermal interface material.

11. The portable baking assembly of claim 10, further comprising a controller communicably coupled with the thermocouple, the controller operable to receive the measured temperature of the thermal interface material.

12. The portable baking assembly of claim 11, wherein the controller is operable to determine when the thermal interface material is cured.

13. The portable baking assembly of claim 12, wherein the controller is operable to indicate to a user that the thermal interface material is cured.

14. A portable system comprising:
a heating device operable to deliver heated air;
a processing unit assembly including a processing unit, a thermal solution, and a thermal interface material operable to couple the processing unit and the thermal solution;
a portable baking assembly including:
a portable housing;
a receiving base disposed in the portable housing, the receiving base operable to receive the processing unit assembly; and
an air flow assembly received in the portable housing and in fluid communication with the receiving base, the air flow assembly including an inlet conduit in fluid communication with the heating device, wherein the inlet conduit is operable to receive heated air from the heating device and direct the heated air towards the receiving base to heat the processing unit assembly and cure the thermal interface material.

15. The portable system of claim 14, wherein the air flow assembly includes an exhaust in fluid communication with the receiving base, wherein the receiving base directs the heated air towards the exhaust to flow out of the portable housing opposite the inlet.

16. The portable system of claim 14, wherein the receiving base includes a flow adapter, the flow adapter operable to direct the heated air to flow across the processing unit assembly to uniformly heat the processing unit assembly and cure the thermal interface material.

17. The portable system of claim 14, further comprising an insulative layer received in the portable housing, wherein the insulative layer is operable to receive the inlet conduit and the receiving base.

18. The portable system of claim 14, further comprising a thermocouple operable to measure the temperature of the thermal interface material and a controller communicably coupled with the thermocouple, the controller operable to receive the measured temperature of the thermal interface material.

19. The portable system of claim 14, wherein the heating device includes an adjustable temperature heat gun.

20. The portable system of claim 14, wherein the heating device is removably coupled with the portable housing.
